(19) United States
(12) Patent Application Publication
(10) Pub. No.: US 2020/0167511 A1
(43) Pub. Date: May 28, 2020

(54) METHOD FOR DESIGNING SUPPORT DAMPING STRUCTURE

(71) Applicant: Ningbo Polytechnic, Ningbo (CN)

(72) Inventors: Yao QIU, Ningbo (CN); Sen QIU, Ningbo (CN)

(21) Appl. No.: 16/691,545

(22) Filed: Nov. 21, 2019

(30) Foreign Application Priority Data
Nov. 22, 2018 (CN) 201811397689 .0

(51) Int. Cl. G06F 30/13; F16F 7/00; G06F 30/20

(52) U.S. Cl. CPC G06F 30/13; E04B 1/98; G06F 30/20; F16F 7/00

(57) ABSTRACT

A method for designing a support damping structure. A total effective damping ratio of the additional support damping structure is preset. A size of an equivalent strut in the structure is assumed, and the equivalent strut is placed at a position where an additional damper is required to be placed. A structural response of the additional damper to the preset total effective damping ratio is calculated; a horizontal resultant of the equivalent strut and a horizontal displacement of the equivalent strut are calculated. A yield strength of the additional damper and a yield displacement of the additional damper are estimated according to the horizontal resultant of the equivalent strut and the horizontal displacement of the equivalent strut. A size of the actual strut in the structure is determined; a total effective damping ratio of the additional support damping structure is obtained.

### CROSS-REFERENCE TO RELATED APPLICATIONS

This application claims the benefit of priority from Chinese Patent Application No. 201811397689.0, filed on Nov. 22, 2018. The content of the aforementioned application, including any intervening amendments thereto, is incorporated herein by reference in its entirety.

### TECHNICAL FIELD

This application relates to energy dissipation of architecture structures, and more particularly to a method for designing a support damping structure.

### BACKGROUND OF THE INVENTION

Compared with the last seismic zonation map, the latest seismic zonation map, Seismic Ground Motion Parameter Zonation Map of China (GB18306-2015), appropriately improves overall requirements for seismic fortification in China, highlights anti-collapse standards of constructions, and eliminates areas free of fortification, which provides a scientific basis for comprehensively improving the seismic fortification capability of China in the new era to better satisfy current economic and social developments in China. In order to meet the requirements of the structural seismic fortification and to control the cost, energy dissipation systems are currently being promoted. The design for the energy dissipation structures is also clearly specified in Code for Seismic Design of Buildings (GB50011-2010). However, currently, energy dissipation devices can not be suitably simulated by conventional softwares, which seriously hinders the promotion of the energy dissipation systems.

Chinese Patent No. 204850121 U discloses an embedded energy dissipation structure with a metal damper, including a steel framework, where an energy dissipation device is arranged in the steel framework, and the energy dissipation device is a support damper or wall damper, and a periphery of the steel framework is fixedly connected to a main structural beam or a main structural column via a connecting key or a layer with a connecting key and a filling material. In the embedded energy dissipation structure with a metal damper, the energy dissipation device is arranged in the steel framework, and a connecting device is arranged at the periphery of the steel framework to allow the energy dissipation structure and the main structure to suffer the force together during an earthquake. When the connecting device adopts the connecting key and the filling material, it is convenient to mount the energy dissipation structure to a beam column of a built construction; when the connecting device adopts a connecting key, it is convenient to mount the energy dissipation structure to a beam column of a building construction. The energy dissipation structure is firm, has high integrity for mounting and good seismic capability. However, this scheme cannot set parameters of the damping structure to be close to corresponding parameters of the target damping ratio, so an effective anti-seismic effect cannot be achieved.

### SUMMARY OF THE INVENTION

To overcome the shortcomings of the prior art, this invention provides a method for designing a support damping structure, which calculates and designs additional support damping structures of buildings, and has simple calculation process, stronger operability and applicability.

To achieve the above-mentioned objective, the invention adopts the following technical solutions.

Provided is a method for designing a support damping structure, comprising:

presetting a total effective damping ratio ξ0 of an additional support damping structure;

assuming a size of an equivalent strut in the additional support damping structure, and placing the equivalent strut at a position on which an additional damper is required to be placed;

calculating a structural response of the additional damper to the preset total effective damping ratio ξ0;

calculating an axial force F_{N} and a support angle θ and a support axial stiffness K of the equivalent strut using an analysis software, where

K is calculated according to an equation K=EA₀/L; E is the elastic modulus of the equivalent strut, A₀ is the area of the equivalent strut, L is the length of the equivalent strut;

calculating a horizontal resultant F of the equivalent strut and a horizontal displacement ΔU_{dmax} of the equivalent strut according to equations F=2F_{N}·cos θ and ΔU_{dmax}=F_{N}/(K·cos θ), respectively;

estimating a yield strength Fdy and a yield displacement dy of the additional damper according to the horizontal resultant F and the horizontal displacement ΔUdmax, where F_{dy}=F;

determining a minimum yield displacement dy of the damper according to a displacement ratio limit Δd under a strong earthquake, and dy=Δd·H/25, where H is the height of the additional support damping structure;

setting a height of the additional damper as h_{d}, iterating an area Aₐ of an actual strut which is larger than the area of the equivalent strut, where Aₐ is approximately 1.2 times of A₀, where an axial stiffness Kₐ of the actual strut is calculated by an equation Kₐ=EAₐ/Lₐ, where Lₐ is a length of the actual strut; an axial displacement d_{aN} of the actual strut is calculated by an equation d_{aN}=F/(2·cos θ·Kₐ); a horizontal deformation d of the actual strut is calculated by an equation d=d_{aN}/cos θ;

determining a size of the actual strut in the additional support damping structure and calculating an effective damping ratio ξd added by the additional damper;

adding the effective damping ratio ξd added by the additional damper and a standard damping ratio of an additional damper to obtain a total effective damping ratio ξ1 of the additional support damping structure, where

the standard damping ratio of the additional dampers is valued as 0.05 for concrete structures and as 0.02-0.04 for steel structures according to specification requirements;

determining whether an error between the preset total effective damping ratio ξ0 of the additional support damping structure and the total effective damping ratio ξ1 of the additional support damping structure is within a preset range, and if the error is within the preset range, determining respective parameters of the additional support damping structure according to the total effective damping ratio ξ1 of the additional support damping structure; and if not, adjusting the number and size of the equivalent strut in the additional support damping structure to determine the respective parameters of the additional support damping structure.

In some embodiments, the method further comprises:

calculating, using PKPM, the structural response of the additional support damping structure to the preset total effective damping ratio ξ0 of the additional support damping structure.

In some embodiments, the structural response comprises a standard internal force of the equivalent strut; and the horizontal resultant F of the equivalent strut is calculated according to the standard internal force of the equivalent strut.

In some embodiments, a stiffness of the equivalent strut is obtained according to basic information of the equivalent strut, where the horizontal displacement of the additional support damping structure ΔU_{dmax} is obtained by the following steps:

calculating an axial displacement of the equivalent strut according to the standard internal force of the equivalent strut, the size and the stiffness of the equivalent strut; and

calculating the horizontal displacement ΔU_{dmax} of the additional support damping structure according to the axial displacement of the equivalent strut.

In some embodiments, the method further comprises:

calculating the horizontal deformation d of the actual strut;

calculating a yield displacement ΔU_{dy} of the additional support damping structure according to the horizontal deformation d of the actual strut and a yield displacement d_{y} of the additional damper.

In some embodiments, the horizontal deformation d of the actual strut is calculated by the following steps:

calculating an axial stiffness of the actual strut;

calculating an axial force of the actual strut according to the axial stiffness of the actual strut and a yield force of the additional damper;

calculating the horizontal deformation d of the actual strut according to the axial force of the actual strut.

In some embodiments, the effective damping ratio ξd added by the additional damper is calculated according to an equation:

ξd=W_{c}/(4πWₛ);

where Wc represents the total energy consumption of n dampers and is calculated according to an equation

$${W}_{c} = {\sum }_{i = 1}^{n} {W}_{ci} ;$$

Wci represents the energy consumption of each of the dampers and is calculated according to an equation Wci=4Fdy(ΔUdmax−ΔUdy); Fdy is the yield force of the additional damper; ΔUdmax is the horizontal displacement of the additional support damping structure; ΔUdy is the yield displacement of the additional support damping structure; Ws represents a total strain energy of the additional support damping structure under an horizontal seismic function without taking torsion effects into consideration and is calculated according to an equation:

$${W}_{s} = \frac{\sum {F}_{i} {u}_{i}}{2} ;$$

where Fᵢ is the standard horizontal seismic function of level i; uᵢ is the displacement corresponding to the standard horizontal seismic function of level i.

Compared with the prior art, the invention calculates and designs the additional support damping structure of buildings. The parameters of the additional support damping structure are adjusted and iterated according to the calculated effective damping ratio of the additional support damping structure until the effective damping ratio of the additional support damping structure is close to the target effective damping ratio, and then the number and model of the damper are determined. The invention has more specific calculation and stronger applicability, which effectively promotes the building structure with the additional support damping structure to achieve a better energy dissipation and seismic mitigation effect.

### BRIEF DESCRIPTION OF THE DRAWINGS

FIG. 1 is a flow chart of a method for designing a support damping structure according to Example 1 of the invention.

FIG. 2 is a force-displacement hysteresis curve of an additional support damping structure of the method for designing the support damping structure according to Example 1 of the invention.

FIG. 3 is a schematic diagram of the additional support damping structure of the method for designing the support damping structure according to Example 1 of the invention.

FIG. 4 shows an iterative calculation process of the method for designing the support damping structure according to Example 1 of the invention.

### DETAILED DESCRIPTION OF EMBODIMENTS

The technical solutions of the invention will be further described with reference to the embodiment and drawings. However, the embodiment is not intended to limit the invention.

### Example 1

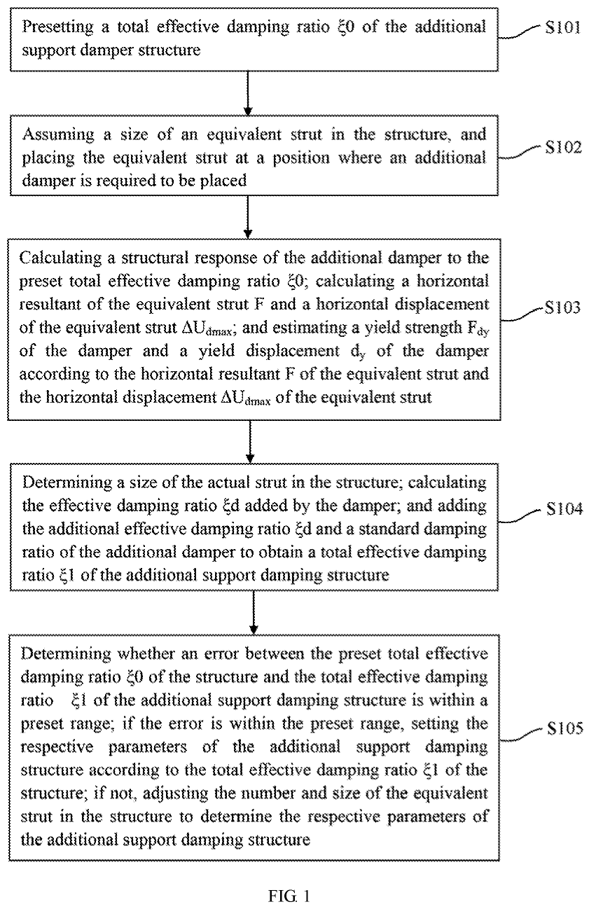

As shown in FIG. 1, the example provides a method for designing a support damping structure, which is specifically described as follows.

S101) A total effective damping ratio ξ0 of an additional support damping structure is preset.

S102) A size of an equivalent strut in the additional support damping structure is assumed, and the equivalent strut is placed at a position on which an additional damper is required to be placed.

S103) A structural response of the additional damper to the preset total effective damping ratio ξ0 is calculated;

a horizontal resultant F of the equivalent strut and a horizontal displacement ΔU_{dmax} of the equivalent strut are calculated; and

a yield strength F_{dy} of the damper and a yield displacement d_{y} of the damper are estimated according to the horizontal resultant F of the equivalent strut and the horizontal displacement ΔU_{dmax} of the equivalent strut.

S104) A size of the actual strut in the additional support damping structure is determined;

the effective damping ratio ξd added by the additional damper is calculated; and

the effective damping ratio ξd added by the additional damper and a standard damping ratio of an additional damper are added to obtain a total effective damping ratio ξ1 of the additional support damping structure.

S105) An error between the preset total effective damping ratio ξ0 of the additional support damping structure and the total effective damping ratio ξ1 of the additional support damping structure is determined whether to be within a preset range, and

if the error is within the preset range, the respective parameters of the additional support damping structure are determined according to the total effective damping ratio ξ1 of the additional support damping structure; and if not, the number and size of the equivalent strut in the additional support damping structure are adjusted to determine the respective parameters of the additional support damping structure.

To promote the additional support damping structure to achieve a good energy dissipation and seismic mitigation effect in the building structure, the example provides an iterative calculation capable of using a conventional structure designing software to design an energy dissipation structure, which obtains respective parameters of the support damper rapidly, including the size of the brace, the number and parameters of the damper. The method further designs the additional support damping structure using PKPM. According to the Chinese specification requirements, the damper works via the difference of the stiffness between the equivalent strut and the actual strut, and consumes energy via the relative displacement, thereby protecting the main structure. The example has simple calculation process, stronger operability and applicability.

In step 101, the total effective damping ratio ξ0 of the additional support damping structure is preset according to a target requirement.

In step 102, the initial conditions are assumed, where a section area of the equivalent strut in the additional support damping structure is assumed, and the equivalent strut is placed at a position on which an additional damper is required to be placed. The equivalent strut and the damper are arranged shown in FIG. 3. A stiffness of the brace can be obtained according to the basic information of the brace.

In step 103, the horizontal resultant F of the equivalent strut and the horizontal displacement ΔU_{dmax} of the equivalent strut are calculated according to the structural response of the additional damper to the preset total effective damping ratio ξ0; and

the yield strength F_{dy} of the damper and the yield displacement d_{y} of the damper are estimated according to the horizontal resultant F of the equivalent strut and the horizontal displacement ΔU_{dmax} of the equivalent strut.

In some embodiments, the method further calculates the response of the additional support damping structure to the preset total effective damping ratio ξ0 of the additional support damping structure using PKPM.

The structural response including a standard internal force of the equivalent strut and the like can be obtained by a calculation for the additional support damping structure using PKPM;

an axial displacement of the equivalent strut is calculated according to the standard internal force of the equivalent strut, the section area and the stiffness of the equivalent strut;

the horizontal displacement ΔU_{dmax} of the additional support damping structure is calculated according to the axial displacement of the equivalent strut;

the horizontal resultant F of the equivalent strut is calculated according to the standard internal force of the equivalent strut.

In step 104, the total effective damping ratio ξ1 of the additional support damping structure is calculated as follows.

a) A section area of the actual strut is determined to have a size larger than the area of the equivalent strut; a support angle between the actual strut and the horizontal plane is calculated; a yield strength F_{dy} of the damper is estimated equally to the horizontal resultant of the equivalent strut; and a yield displacement of the damper and a height of the damper are defined.

In some embodiments, in step 104, the horizontal deformation d of the actual strut is further calculated.

The horizontal deformation d of the actual strut and a yield displacement d_{y} of the additional damper are added to obtain a yield displacement ΔU_{dy} of the damping structure.

In some embodiments, the horizontal deformation d of the actual strut is obtained successively by calculating an axial stiffness of the actual strut, calculating an axial force of the actual strut according to the axial stiffness of the actual strut and a yield force of the damper, and finally calculating the horizontal deformation d of the actual strut according to the axial force of the actual strut.

b) The total effective damping ratio ξ1 of the additional support damping structure is calculated by adding the effective damping ratio ξd added by the additional damper and a standard damping ratio of an additional damper.

In some embodiments, the effective damping ratio ξd added by the additional damper is calculated according to an equation:

ξd=W_{c}/(4πWₛ);

where W_{c} represents the total energy consumption of n dampers and is calculated according to an equation

$${W}_{c} = {\sum }_{i = 1}^{n} {W}_{ci} ;$$

W_{ci} represents the energy consumption of each of the dampers and is calculated according to an equation W_{ci}=4F_{dy}(ΔU_{dmax}−ΔU_{dy}); F_{dy} is the yield force of the additional damper; ΔU_{dmax} is the horizontal displacement of the additional support damping structure; ΔU_{dy} is the yield displacement of the damping structure;

Ws represents a total strain energy of the additional support damping structure under an horizontal seismic function without taking torsion effects into consideration and is calculated according to an equation:

$${W}_{s} = \frac{\sum {F}_{i} {u}_{i}}{2} ;$$

where Fᵢ is the standard horizontal seismic function of level i; uᵢ is the displacement corresponding to the standard horizontal seismic function of level i.

In step 105, the effective damping ration is reviewed and calculated by iteration.

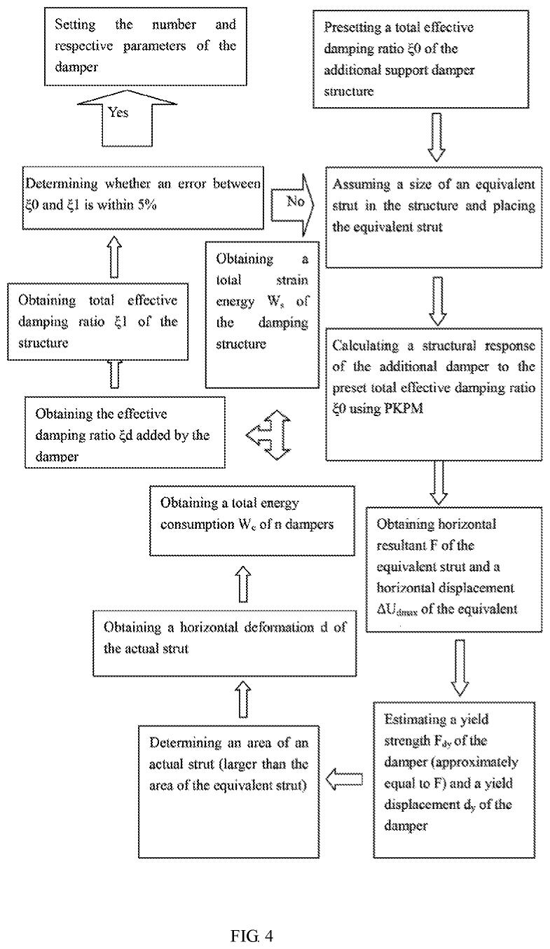

An error between the preset total effective damping ratio ξ0 of the additional support damping structure and the total effective damping ratio ξ1 of the additional support damping structure is determined whether to be within a preset range, which is 5% in Example 1, and if the error is out of the preset range, the number and size of the equivalent strut in the additional support damping structure are adjusted, then the process is turned back to step 102 for iteration again until the error between 1 and is within 5%. An iterative calculation process of the method according to Example 1 is schematically shown in FIG. 4.

The invention adopts the following specific scheme.

In the invention, the equivalent damping ratio added by the additional damper to the structure is derived and calculated according to the provisions of Chapter 12 of Code for Seismic Design of Buildings (GB50011-2010).

The energy consumption of the dampers is calculated according to the provisions of Chapter 3 of Technical Specification for Architecture Energy Dissipation JGJ297-2013. The energy consumption of the damper per week is calculated by an equation W_{c}=4F_{dy}(ΔU_{dmax}−ΔU_{dy}), where F_{dy} is a yield force of the damper, ΔU_{dmax} is a horizontal displacement of the additional support damping structure, ΔU_{dy} is the yield displacement of the damping structure.

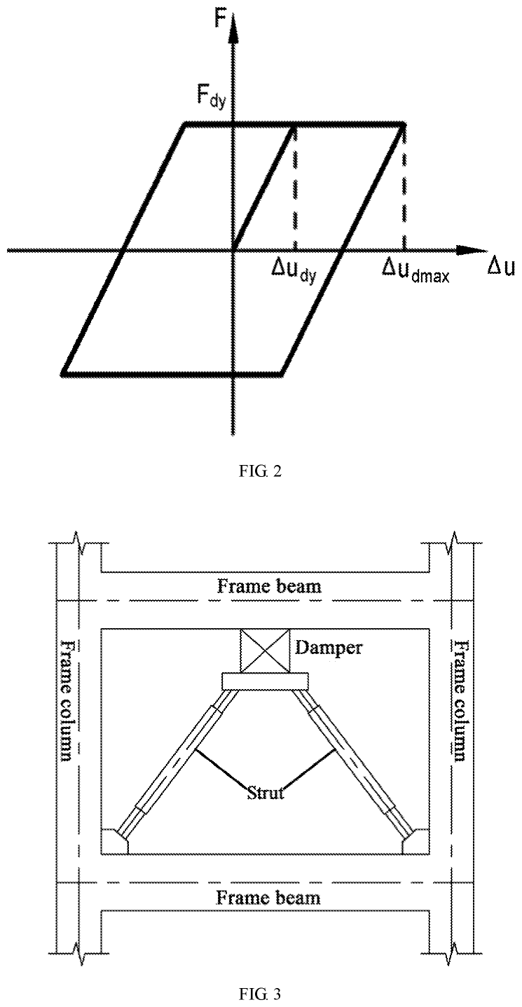

FIG. 2 is a force-displacement hysteresis curve of an additional support damping structure, where F_{dy} can be calculated according to an axial force of the equivalent strut, ΔU_{dmax} can be calculated according to the axial force and the stiffness of the equivalent strut, and ΔU_{dy} includes a yield displacement of the damper and the horizontal deformation of the actual strut;

Wₛ represents a total strain energy of the damper structure under an horizontal seismic function without taking consideration of torsion effects and is calculated according to an equation Wᵢ=ΣFᵢuᵢ/2, Fᵢ is a horizontal seismic function standard value of level i, uᵢ is a displacement corresponding to the horizontal seismic function standard value of level i;

the effective damping ratio added by the damper d is calculated by an equation:

ξd=W_{c}/(4πWₛ);

an error between the preset total effective damping ratio of the structure ξ0 and the total effective damping ratio of the actually configured structure ξ1 is determined whether to be out of 5%; if the error is out of 5%, the amount and size of the equivalent strut in the structure are adjusted to reset the respective parameters of the additional damper structure; if the error is within 5%, then the optimal amount and parameters of the additional damper structure are obtained.

The invention has the following beneficial effects.

The method for designing an additional support damping structure provided in the invention has advantages of effective calculation, convenient applicability and strong operability, specifically shown as follows.

(1) The invention employs Code for Seismic Design of Buildings GB50011-2010 as a theory basis, which ensures that the calculated results are accurate and reliable and the method is suitable for designing actual engineering projects.

(2) The invention employs PKPM for the structural calculation, which is a conventional analysis software for structural designing. The invention also uses Microsoft Excel to compile data processing forms, which is convenient for promoting the method in the field of structural design.

(3) The invention has common applicability and is applicable to conventional displacement-typed dampers, such as metal dampers, friction dampers, and etc.

The specific embodiments described herein are merely illustrative of the spirit of the invention. Any modifications, additions and equivalent substitutions made by those skilled in the art within the spirit and principle of the invention shall fall into the scope of the invention.

What is claimed is:

1. A method for designing a support damping structure, comprising:
presetting a total effective damping ratio ξ0 of an additional support damping structure;
assuming a size of an equivalent strut in the additional support damping structure, and placing the equivalent strut at a position on which an additional damper is required to be placed;
calculating a structural response of the additional damper to the preset total effective damping ratio ξ0;
calculating an axial force F_{N} and a support angle θ and a support axial stiffness K of the equivalent strut using an analysis software, wherein K is calculated according to an equation K=EA₀/L; E is the elastic modulus of the equivalent strut, A₀ is the area of the equivalent strut, L is the length of the equivalent strut;
calculating a horizontal resultant F of the equivalent strut and a horizontal displacement ΔU_{dmax} of the equivalent strut according to equations F=2F_{N}·cos θ and ΔU_{dmax}=F_{N}/(K·cos θ), respectively;
estimating a yield strength F_{dy} and a yield displacement d_{y} of the additional damper according to the horizontal resultant F and the horizontal displacement ΔU_{dmax}, where F_{dy}=F;
determining a minimum yield displacement d_{y} of the additional damper according to a displacement ratio limit Δd under a strong earthquake, and d_{y}=Δd·H/25, where H is the height of the additional support damping structure;
setting a height of the additional damper as h_{d}, iterating an area Aa of an actual strut which is larger than the area of the equivalent strut, where Aₐ is approximately 1.2 times of A₀, where an axial stiffness Ka of the actual strut is calculated by an equation Kₐ=EAₐ/Lₐ, where Lₐ is a length of the actual strut; an axial displacement d_{aN} of the actual strut is calculated by an equation d_{aN}=F/(2·cos θ·Kₐ); a horizontal deformation d of the actual strut is calculated by an equation d=d_{aN}/cos θ;
determining a size of the actual strut in the additional support damping structure and calculating an effective damping ratio ξd added by the additional damper;
adding the effective damping ratio ξd added by the additional damper and a standard damping ratio of additional dampers to obtain a total effective damping ratio ξ1 of the additional support damping structure, wherein the standard damping ratio of the additional dampers is valued as 0.05 for concrete structures and as 0.02-0.04 for steel structures according to specification requirements; and
determining whether an error between the preset total effective damping ratio ξ0 of the additional support damping structure and the total effective damping ratio ξ1 of the additional support damping structure is within a preset range, and if the error is within the preset range, determining respective parameters of the additional support damping structure according to the total effective damping ratio ξ1 of the additional support damping structure; and if not, adjusting the number and size of the equivalent strut in the additional support damping structure to determine the respective parameters of the additional support damping structure.

2. The method of claim 1, further comprising: calculating, using PKPM, the structural response of the additional support damping structure to the preset total effective damping ratio ξ0 of the additional support damping structure.

3. The method of claim 1, wherein the structural response comprises a standard internal force of the equivalent strut; and the horizontal resultant F of the equivalent strut is calculated according to the standard internal force of the equivalent strut.

4. The method of claim 1, wherein a stiffness of the equivalent strut is obtained according to basic information of the equivalent strut, wherein the horizontal displacement of the additional support damping structure ΔUdmax is obtained by a method comprising the following steps:
calculating an axial displacement of the equivalent strut according to the standard internal force of the equivalent strut, the size and the stiffness of the equivalent strut; and
calculating the horizontal displacement ΔUdmax of the additional support damping structure according to the axial displacement of the equivalent strut.

5. The method of claim 1, further comprising:
calculating the horizontal deformation d of the actual strut; and
calculating a yield displacement ΔU_{dy} of the additional support damping structure according to the horizontal deformation d of the actual strut and a yield displacement dy of the additional damper.

6. The method of claim 5, wherein the horizontal deformation d of the actual strut is calculated by a method comprising steps of:
calculating an axial stiffness of the actual strut;
calculating an axial force of the actual strut according to the axial stiffness of the actual strut and a yield force of the additional damper; and
calculating the horizontal deformation d of the actual strut according to the axial force of the actual strut.

7. The method of claim 1, wherein the effective damping ratio ξd added by the additional damper is calculated according to the following equation:
ξd=W_{c}/(4πWₛ);
wherein W_{c} represents the total energy consumption of n dampers and is calculated according to the following equation:
$$Wc = {\sum }_{i = 1}^{n} {W}_{ci} ;$$
wherein W_{ci} represents the energy consumption of each of the dampers and is calculated according to an equation W_{ci}=4F_{dy}(ΔU_{dmax}−ΔU_{dy}); F_{dy} is the yield force of the additional damper; ΔU_{dmax} is the horizontal displacement of the additional support damping structure; ΔU_{dy} is the yield displacement of the additional support damping structure;
Wₛ represents a total strain energy of the additional support damping structure under an horizontal seismic function without taking torsion effects into consideration and is calculated according to the following equation:
$${W}_{s} = \frac{\sum {F}_{i} {u}_{i}}{2} ;$$
wherein Fᵢ is the standard horizontal seismic function of level i; uᵢ is the displacement corresponding to the standard horizontal seismic function of level i.
